(19) United States
(12) Patent Application Publication
(10) Pub. No.: US 2024/0222087 A1
(43) Pub. Date: Jul. 4, 2024

(54) SUBSTRATE PROCESSING APPARATUS, PLASMA GENERATING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Tsuyoshi TAKEDA, Toyama (JP); Daisuke HARA, Toyama (JP)

(21) Appl. No.: 18/609,531

(22) Filed: Mar. 19, 2024

Related U.S. Application Data
(63) Continuation of application No. PCT/JP2021/034890, filed on Sep. 22, 2021.

(51) Int. Cl. H01J 37/32

(52) U.S. Cl. CPC H01J 37/32522; H01J 37/32449; H01J 37/32715; H01J 37/32816

(57) ABSTRACT

There is provided a technique that includes: a process vessel accommodating therein a process chamber where a substrate is processed; a gas supplier through which a gas is supplied into the process chamber; and a first plasma generator configured to generate a plasma of the gas in the process chamber and including: an insulator provided so as to protrude into the process chamber; a coil of a planar shape arranged in the insulator; and an adjuster capable of adjusting a gap distance between the coil and the insulator.

### CROSS REFERENCE TO RELATED APPLICATIONS

This application is a bypass continuation application of PCT International Application No. PCT/JP2021/034890, filed on Sep. 22, 2021, in the WIPO, the entire contents of which are hereby incorporated by reference.

### TECHNICAL FIELD

The present disclosure relates to a substrate processing apparatus, a plasma generating apparatus, a substrate processing method, a method of manufacturing a semiconductor device and a non-transitory computer-readable recording medium.

### BACKGROUND

A circuit pattern of a semiconductor device such as a large scale integrated circuit, a DRAM (dynamic random access memory) and a flash memory is miniaturized as the semiconductor device is highly integrated. According to some related arts, in a manufacturing process of the semiconductor device, a process using a plasma may be performed as a process for realizing a miniaturization of the circuit pattern.

In the manufacturing process of the semiconductor device, a substrate processing may be performed by supplying a predetermined gas to a semiconductor substrate (hereinafter, also simply referred to as a “substrate”). In the substrate processing, it is preferable to uniformly form a film on a surface of the substrate. However, when a surface area of the substrate increases, for example, as the circuit pattern is miniaturized, an active species of an activated gas may be consumed on an increased surface of the substrate. Thereby, a supply of the gas (that is, the active species of the activated gas) may be insufficient. As a result, the film whose distribution is non-uniform on the surface of the substrate may be formed.

### SUMMARY

According to the present disclosure, there is provided a technique capable of uniformly forming a film on a surface of a substrate by controlling a plasma distribution.

According to an aspect of the present disclosure, there is provided a technique that includes: a process vessel accommodating therein a process chamber where a substrate is processed; a gas supplier through which a gas is supplied into the process chamber; and a first plasma generator configured to generate a plasma of the gas in the process chamber and including: an insulator provided so as to protrude into the process chamber; a coil of a planar shape arranged in the insulator; and an adjuster capable of adjusting a gap distance between the coil and the insulator.

### BRIEF DESCRIPTION OF THE DRAWINGS

FIG. 1 is a diagram schematically illustrating a substrate processing apparatus according to a first embodiment of the present disclosure.

FIG. 2A is a diagram schematically illustrating a combination of an insulator and a coil of the substrate processing apparatus according to the first embodiment of the present disclosure.

FIG. 2B is a diagram schematically illustrating another combination of the insulator and the coil of the substrate processing apparatus according to the first embodiment of the present disclosure.

FIG. 2C is a diagram schematically illustrating still another combination of the insulator and the coil of the substrate processing apparatus according to the first embodiment of the present disclosure.

FIG. 2D is a diagram schematically illustrating still another combination of the insulator and the coil of the substrate processing apparatus according to the first embodiment of the present disclosure.

FIG. 2E is a diagram schematically illustrating still another combination of the insulator and the coil of the substrate processing apparatus according to the first embodiment of the present disclosure.

FIG. 3 is a graph schematically illustrating a radial distribution of a plasma density in the substrate processing apparatus according to the first embodiment of the present disclosure.

FIG. 4A is a diagram schematically illustrating an exemplary radial distribution of the plasma density in the substrate processing apparatus according to the first embodiment of the present disclosure.

FIG. 4B is a diagram schematically illustrating another exemplary radial distribution of the plasma density in the substrate processing apparatus according to the first embodiment of the present disclosure.

FIG. 5 is a block diagram schematically illustrating a configuration of a controller and related components of the substrate processing apparatus according to the first embodiment of the present disclosure.

FIG. 6 is a flow chart schematically illustrating a substrate processing according to the first embodiment of the present disclosure.

FIG. 7 is a diagram schematically illustrating an exemplary sequence of the substrate processing according to the first embodiment of the present disclosure.

FIG. 8 is a diagram schematically illustrating a substrate processing apparatus according to a second embodiment of the present disclosure.

FIG. 9 is a diagram schematically illustrating a substrate processing apparatus according to a third embodiment of the present disclosure.

### DETAILED DESCRIPTION

Hereinafter, embodiments according to the technique of the present disclosure will be described.

### First Embodiment of Present Disclosure

Hereinafter, a first embodiment according to the technique of the present disclosure will be described in detail mainly with the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

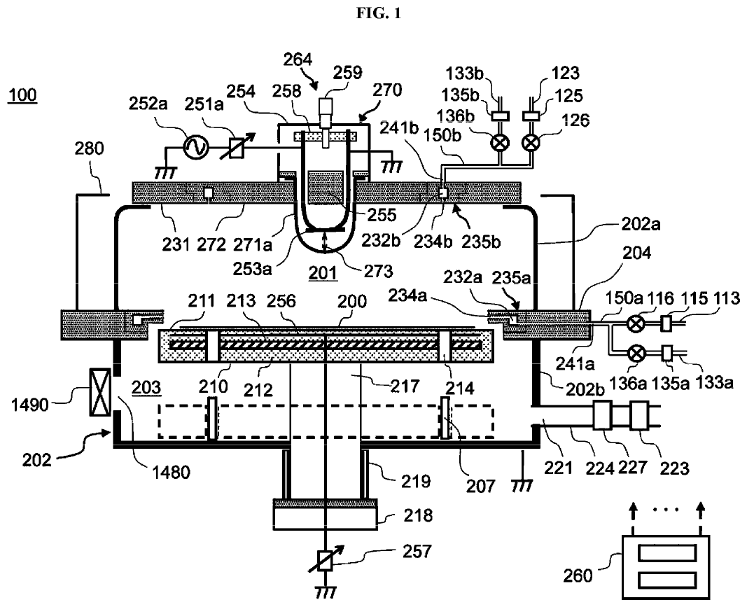

First, a configuration of a substrate processing apparatus 100 according to the first embodiment of the present disclosure will be described. For example, the substrate processing apparatus 100 is configured as an insulating film forming apparatus. As shown in FIG. 1, the substrate processing apparatus 100 may be configured as a single wafer type substrate processing apparatus.

### <Process Vessel>

As shown in FIG. 1, the substrate processing apparatus 100 includes a process vessel 202. For example, the process vessel 202 is configured as a flat and sealed vessel whose horizontal cross-section is of a circular shape. For example, the process vessel 202 is made of a metal such as aluminum (Al) and stainless steel (SUS) or made of an insulating material such as quartz and alumina. A process chamber 201 in which a wafer (which is a substrate) 200 such as a silicon wafer is processed and a transfer chamber 203 located below the process chamber 201 are provided in the process vessel 202. The process vessel 202 is constituted mainly by a lid 231, an upper vessel 202a, a lower vessel 202b and a partition plate 204 provided between the upper vessel 202a and the lower vessel 202b. Further, a space surrounded by the lid 231, the upper vessel 202a, the partition plate 204, a second gas distributor (which is a second gas distribution structure or a second gas dispersion structure) 235b described later and a plasma generator (also referred to as a “plasma unit” or a “plasma generating structure”) 270 to be described later may also be referred to as the “process chamber 201”, and a space surrounded by the lower vessel 202b may also be referred to as the “transfer chamber 203”.

A shield plate 280 is provided outside the process vessel 202 to shield its inner structure from a radiant heat from a heater 213 described later and an electromagnetic wave radiated from a coil 253a serving as a first coil described later. The shield plate 280 is of a cylindrical shape, and is grounded.

A substrate loading/unloading port 1480 is provided adjacent to a gate valve 1490 at a side surface of the lower vessel 202b. The wafer 200 is transferred between the transfer chamber 203 and a vacuum transfer chamber (not shown) through the substrate loading/unloading port 1480. A plurality of lift pins 207 are provided at a bottom of the lower vessel 202b. In addition, the lower vessel 202b is electrically grounded.

A substrate support (which is a substrate supporting structure) 210 configured to support the wafer 200 is provided in the process chamber 201. The substrate support 210 mainly includes: a substrate mounting table 212 provided with a substrate placing surface 211 on which the wafer 200 is placed; the heater 213 serving as a heating structure embedded in the substrate mounting table 212; and a susceptor electrode 256 embedded in the substrate mounting table 212 in a manner similar to the heater 213. A plurality of through-holes 214 through which the lift pins 207 penetrate are provided at positions of the substrate mounting table 212 in a manner corresponding to the lift pins 207, respectively.

A bias regulator (which is a bias adjusting structure) 257 is connected to the susceptor electrode 256 such that an electric potential of the susceptor electrode 256 is capable of being adjusted. The bias regulator 257 is configured to adjust the electric potential of the susceptor electrode 256 by a controller 260 described later.

The substrate mounting table 212 is supported by a shaft 217. The shaft 217 penetrates the bottom of the lower vessel 202b, and is connected to an elevator 218 serving as an elevating structure outside the lower vessel 202b. The wafer 200 placed on the substrate placing surface 211 of the substrate mounting table 212 may be elevated or lowered by elevating or lowering the shaft 217 and the substrate mounting table 212 by operating the elevator 218. A bellows 219 covers a periphery of a lower end of the shaft 217 to maintain the process chamber 201 airtight.

When the wafer 200 is transferred, the substrate mounting table 212 is lowered to a wafer transfer position indicated by a dashed line in FIG. 1. When the wafer 200 is processed, the substrate mounting table 212 is elevated to a processing position (which is a wafer processing position) shown in FIG. 1. Specifically, when the substrate mounting table 212 is lowered to the wafer transfer position, upper ends of the lift pins 207 protrude from an upper surface of the substrate placing surface 211 through the through-holes 214, and the lift pins 207 support the wafer 200 from thereunder. When the substrate mounting table 212 is elevated to the wafer processing position, the lift pins 207 are buried from the upper surface of the substrate placing surface 211, and the substrate placing surface 211 supports the wafer 200 from thereunder. Further, since the lift pins 207 are in direct contact with the wafer 200, the lift pins 207 are preferably made of a material such as quartz, alumina and silicon carbide.

### <Exhauster>

An exhaust port 221 is provided on the side surface of the lower vessel 202b. An inner atmosphere of the process chamber 201 and an inner atmosphere of the transfer chamber 203 are exhausted through the exhaust port 221. An exhaust pipe 224 is connected to the exhaust port 221. A pressure regulator (which is a pressure adjusting structure) 227 such as an APC (Automatic Pressure Controller) valve and a vacuum pump 223 are sequentially connected to the exhaust pipe 224 in this order so as to adjust an inner pressure of the process chamber 201.

### <Gas Introduction Port>

A first gas introduction port 241a through which various gases are supplied into the process chamber 201 is provided at a side portion of the partition plate 204. In addition, a second gas introduction port 241b through which various gases are supplied into the process chamber 201 is provided at an upper portion of the process chamber 201. The first gas introduction port 241a serves as a first gas supply port, and the second gas introduction port 241b serves as a second gas supply port.

### <Gas Supplier>

A first gas supply pipe 150a is connected to the first gas introduction port 241a. A first process gas supply pipe 113 and a purge gas supply pipe 133a are connected to the first gas supply pipe 150a such that a first process gas described later and a purge gas can be supplied through the first process gas supply pipe 113, the purge gas supply pipe 133a and the first gas supply pipe 150a. A second gas supply pipe 150b is connected to the second gas introduction port 241b. A second process gas supply pipe 123 and a purge gas supply pipe 133b are connected to the second gas supply pipe 150b such that a second process gas described later and the purge gas can be supplied through the second process gas supply pipe 123, the purge gas supply pipe 133b and the second gas supply pipe 150b.

### <First Process Gas Supplier>

A mass flow controller (also simply referred to as an “MFC”) 115 and a valve 116 are provided at the first process gas supply pipe 113. A first process gas supplier (which is a first process gas supply structure or a first process gas supply system) is constituted by the first process gas supply pipe 113, the MFC 115 and the valve 116. Further, the first process gas supplier may further include a first process gas supply source (not shown). In addition, when a source material of the first process gas is in a liquid state or a solid state, a vaporizer (not shown) may be provided. That is, the first process gas supplier may further include the vaporizer.

### <Second Process Gas Supplier>

An MFC 125 and a valve 126 are provided at the second process gas supply pipe 123. A second process gas supplier (which is a second process gas supply structure or a second process gas supply system) is constituted by the second process gas supply pipe 123, the MFC 125 and the valve 126. Further, the second process gas supplier may further include a second process gas supply source (not shown).

### <Purge Gas Supplier>

An MFC 135a and a valve 136a are provided at the purge gas supply pipe 133a. A first purge gas supplier (which is a first purge gas supply structure or a first purge gas supply system) is constituted by the purge gas supply pipe 133a, the MFC 135a and the valve 136a. In addition, an MFC 135b and a valve 136b are provided at the purge gas supply pipe 133b. A second purge gas supplier (which is a second purge gas supply structure or a second purge gas supply system) is constituted by the purge gas supply pipe 133b, the MFC 135b and the valve 136b. That is, as a purge gas supplier (which is a purge gas supply structure or a purge gas supply system), the first purge gas supplier constituted by the purge gas supply pipe 133a, the MFC 135a and the valve 136a and the second purge gas supplier constituted by the purge gas supply pipe 133b, the MFC 135b and the valve 136b are provided. Further, the purge gas supplier may further include a purge gas supply source (not shown).

### <Gas Distributor>

A first gas distributor (which is a first gas distribution structure or a first gas dispersion structure) 235a serving as a structure of distributing (or dispersing) a gas such as the first process gas is connected to the first gas introduction port 241a. The first gas distributor 235a is configured as a ring-shaped configuration constituted by a first buffer chamber 232a and a plurality of first dispersion holes 234a, and is arranged adjacent to the partition plate 204. The first process gas and the purge gas introduced through the first gas introduction port 241a are supplied to the first buffer chamber 232a of the first gas distributor 235a, and then supplied to the process chamber 201 through the plurality of first dispersion holes 234a. Similarly, the second gas distributor 235b serving as a structure of distributing (or dispersing) a gas such as the second process gas is connected to the second gas introduction port 241b. The second gas distributor 235b is configured as a ring-shaped configuration constituted by a second buffer chamber 232b and a plurality of second dispersion holes 234b, and is arranged between the lid 231 and the plasma generator 270 described later. The second process gas and the purge gas introduced through the second gas introduction port 241b are supplied to the second buffer chamber 232b of the second gas distributor 235b, and then supplied to the process chamber 201 through the plurality of second dispersion holes 234b.

### <Plasma Generator>

The plasma generator (plasma generating apparatus) 270 partially protruding into the process chamber 201 is arranged at an upper portion of the upper vessel 202a. The plasma generator 270 serves as a first plasma generator. For example, the plasma generator 270 serving as the plasma generating apparatus is constituted by: an insulator 271a fixed to a pedestal 272; the coil 253a arranged in the insulator 271a; a first electromagnetic wave shield 254 (which is arranged above the coil 253a) and a second electromagnetic wave shield 255 provided to cover the coil 253a; a reinforcing structure (or a fixing structure) 258 reinforced by fixing both ends of the coil 253a with an insulating material such as a resin; and a micrometer 259 (which is a moving structure or a mover capable of vertically moving the coil 253a) including a shaft fixed to the first electromagnetic wave shield 254 and moving vertically while rotating.

For example, the insulator 271a is made of an insulating material such as quartz and alumina, and is provided above the substrate placing surface 211 so as to protrude toward an inner space of the process chamber 201. More specifically, the insulator 271a is located above a central portion of the substrate 200 placed on the substrate placing surface 211. A portion of the insulator 271a arranged to protrude toward the inner space of the process chamber 201 is provided with a curved surface constituting a hemispherical shape or a semi-spheroid shape. Also, the insulator 271a is provided with a hole therein. Further, an inner atmosphere and an outer atmosphere of the insulator 271a are isolated from each other by a vacuum seal. In addition, a diameter of the insulator 271a is set to be smaller than a diameter of the wafer 200.

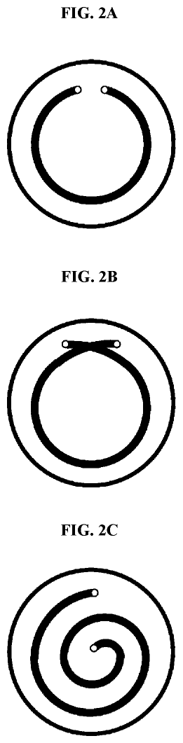

For example, the coil 253a is configured by using a conductive metal pipe, and is provided in the portion of the insulator 271a arranged to protrude toward the inner space of the process chamber 201. The coil 253a is provided so as to be capable of being moved in the vertical direction inside the insulator 271a. When viewed from above, the coil 253a includes a spiral-shaped portion within +10° with respect to the substrate placing surface 211 and a surface of the wafer 200. As shown in FIG. 2A, for example, the coil 253a is of a spiral shape with 0.9 winding turn when viewed from above, and a side portion of the coil 253a is provided along the curved surface of the insulator 271a. In other words, the coil 253a is provided so as to include a portion along the curved surface of the insulator 271a when viewed from above.

The coil 253a is not limited to the configuration described above including the spiral-shaped portion with 0.9 winding turn. As shown in FIGS. 2B through 2E, for example, the coil 253a may be of a spiral shape with 1.5 winding turns, 2 winding turns or 2.5 winding turns, and a spiral direction thereof may change midway. Specifically, FIG. 2B schematically illustrates a spiral-shaped coil with 1.2 winding turns, and FIG. 2C schematically illustrates a spiral-shaped coil with 2 winding turns. Further, FIG. 2D schematically illustrates two spiral-shaped coils with 0.4 winding turn, the same spiral radius and different spiral directions, and FIG. 2E schematically illustrates two spiral-shaped coils with 0.9 winding turn, different spiral radii and different spiral directions. In a manner describe above, the coil 253a may be of a spiral shape with at least 0.4 winding turn. In addition, a diameter of the coil 253a is set to be smaller than the diameter of the wafer 200.

As shown in FIG. 1, a first end (one end) of the coil 253a is connected to a matcher (which is a matching structure) 251a and a high frequency power supply 252a, and a second end (the other end) of the coil 253a is connected to a ground. The first electromagnetic wave shield 254 and the second electromagnetic wave shield 255 are also connected to the ground. A high frequency power from the high frequency power supply 252a is supplied (or applied) between the first end of the coil 253a connected to the matcher 251a and the ground to which the second end of the coil 253a, the first electromagnetic wave shield 254 and the second electromagnetic wave shield 255 are connected.

Each of the first electromagnetic wave shield 254 and the second electromagnetic wave shield 255 is configured by using a conductive metal plate, and of a cylindrical shape or of a rectangular parallelepiped shape. That is, by including the first electromagnetic wave shield 254 and the second electromagnetic wave shield 255, the plasma generator 270 is shielded by the conductive metal plate of the cylindrical shape or of the rectangular parallelepiped shape.

According to the plasma generator 270 configured as described above, when a process gas (in particular, a reactive gas described later serving as the second process gas) is supplied to the process chamber 201, the process gas is induced by an alternating magnetic field created by the coil 253a, and thereby, an inductively coupled plasma (abbreviated as “ICP”) is generated. That is, the plasma generator 270 is configured to generate a plasma of the process gas within the process chamber 201. For generating the plasma, the plasma generator 270 is provided so as to partially protrude into the process chamber 201. Therefore, a portion (or a region) of the plasma that couples (or intersects) with an electromagnetic field emitted from the coil 253a increases, and an efficiency (also referred to as an “input efficiency”) of inputting the high frequency power of the plasma also increases. As a result, it is possible to improve an efficiency (also referred to as a “plasma generation efficiency”) of generating the plasma by the plasma generator 270.

In addition, when the coil 253a of the plasma generator 270 is supplied with the high frequency power from the high frequency power supply 252a, a resistance value gradually increases due to a generation of Joule heat. As a result, the matcher 251a attempting to perform an impedance matching may become unstable. Therefore, in order to stabilize a temperature of a component such as the coil 253a, the high frequency power supply 252a and the matcher 251a, the coil 253a may be cooled with a substance such as water and air such that the resistance value can be maintained constant.

### <Adjusting Structure (Adjuster)>

The shaft of the micrometer 259 included in the plasma generator 270 is fixed to the reinforcing structure (or the fixing structure) 258 via a bearing (not shown). Further, by rotating the micrometer 259, the reinforcing structure 258 and the coil 253a are moved together in the vertical direction. Thereby, it is possible to adjust a gap distance 273 between the coil 253a and an inner wall at a bottom portion of the insulator 271a. More specifically, it is possible to increase the gap distance 273 by moving the coil 253a away from the insulator 271a by rotating the micrometer 259. That is, by moving the coil 253a upward, it is possible to lengthen the gap distance 273 between the coil 253a and the inner wall at the bottom portion of the insulator 271a. In addition, it is also possible to decrease the gap distance 273 by moving the coil 253a closer to the insulator 271a by rotating the micrometer 259. That is, by moving the coil 253a downward, it is possible to shorten the gap distance 273 between the coil 253a and the inner wall at the bottom portion of the insulator 271a. That is, the micrometer 259 and the reinforcing structure 258 are configured to function as an adjusting structure (hereinafter, also simply referred to as an “adjuster”) 264 capable of adjusting the gap distance 273. Further, as long as the gap distance 273 is capable of being adjusted, another configuration may be used as the adjusting structure (adjuster) 264 instead of the above-described configuration including the micrometer 259 and the reinforcing structure 258 serving as the mover.

The plasma generation efficiency of the plasma generator 270 improves as a surface area of the coil 253a facing the insulator 271a increases. Furthermore, since a tip (front end) of the insulator 271a is configured as the curved surface of the hemispherical shape or of the semi-spheroid shape, it is possible to further improve the plasma generation efficiency. In such a case, depending on the gap distance 273, it is also possible to vary (or change) the plasma generation efficiency of the plasma generator 270.

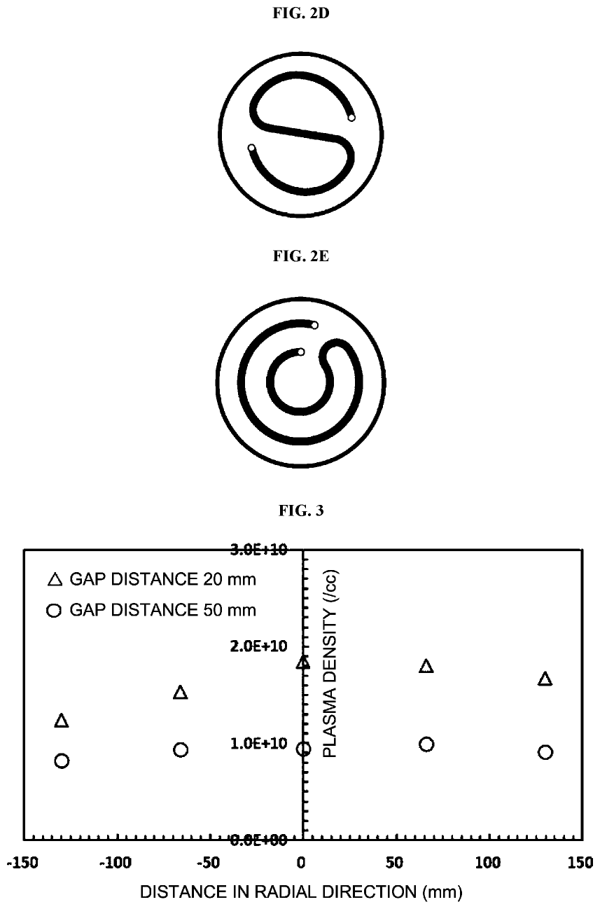

In a graph shown in FIG. 3, shown is a radial distribution of a plasma density (hereinafter, also simply referred to as a “plasma distribution”) under conditions where a nitrogen gas pressure is 10 Pa and the power (high frequency power) of the high frequency power supply 252a is 600 W by using the coil 253a of the spiral shape with 0.9 winding turn shown in FIG. 2A. A horizontal axis of the graph represents a distance in a radial direction of the wafer 200, and a vertical axis of the graph represents the plasma density. When the gap distance 273 is 20 mm, an average of the plasma density is 1.6×1010/cc and a uniformity thereof is +19% (which is high), and when the gap distance 273 is 50 mm, the average of the plasma density is 0.92×1010/cc and the uniformity thereof is +9.5% (which is low).

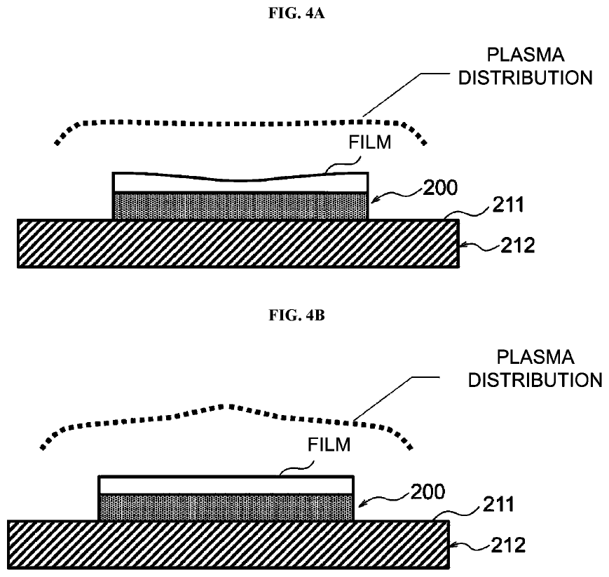

Specifically, by moving the coil 253a upward to increase (lengthen) the gap distance 273 between the coil 253a and the inner wall at the bottom portion of the insulator 271a, in a portion exposed upwardly at an outer peripheral portion (outer periphery) of the wafer 200, a consumption rate of an active species of the reactive gas is reduced. Therefore, as shown in FIG. 4A, when the plasma distribution is uniform in the radial direction of the wafer 200, due to the active species diffusing from a central portion (center) to the outer peripheral portion of the wafer 200, a thickness of a film formed on the outer peripheral portion of the wafer 200 increases. As a result, a thickness distribution of the film formed on the wafer 200 may be formed into a concave distribution as a whole.

On the other hand, as shown in FIG. 4B, by moving the coil 253a downward to decrease (shorten) the gap distance 273 between the coil 253a and the inner wall at the bottom portion of the insulator 271a, the plasma distribution becomes higher at the central portion of the wafer 200. Thus, due to the active species diffusing from the central portion to the outer peripheral portion of the wafer 200, the thickness of the film formed on the central portion of the wafer 200 increases. As a result, the thickness of the film formed on the wafer 200 is uniform as a whole.

In a manner described above, by adjusting the gap distance 273 using the micrometer 259 according to a surface area of the wafer 200, it is possible to control a magnitude of the plasma density and the plasma distribution. By shortening the gap distance 273 between the coil 253a and the inner wall at the bottom portion of the insulator 271a by the adjusting structure 264, the plasma distribution becomes higher at the central portion of the wafer 200. Thereby, it is possible to increase an amount (also referred to as a “generation amount”) of the plasma generated at the central portion of the wafer 200. Further, by shortening the gap distance 273 between the coil 253a and the inner wall at the bottom portion of the insulator 271a by the adjusting structure 264, the plasma distribution is uniform in the radial direction of the wafer 200. As a result, it is possible to reduce the generation amount of the plasma generated at the central portion of the wafer 200.

### <Controller>

As shown in FIG. 1, the substrate processing apparatus 100 includes the controller 260 configured to be capable of controlling the components constituting the substrate processing apparatus 100.

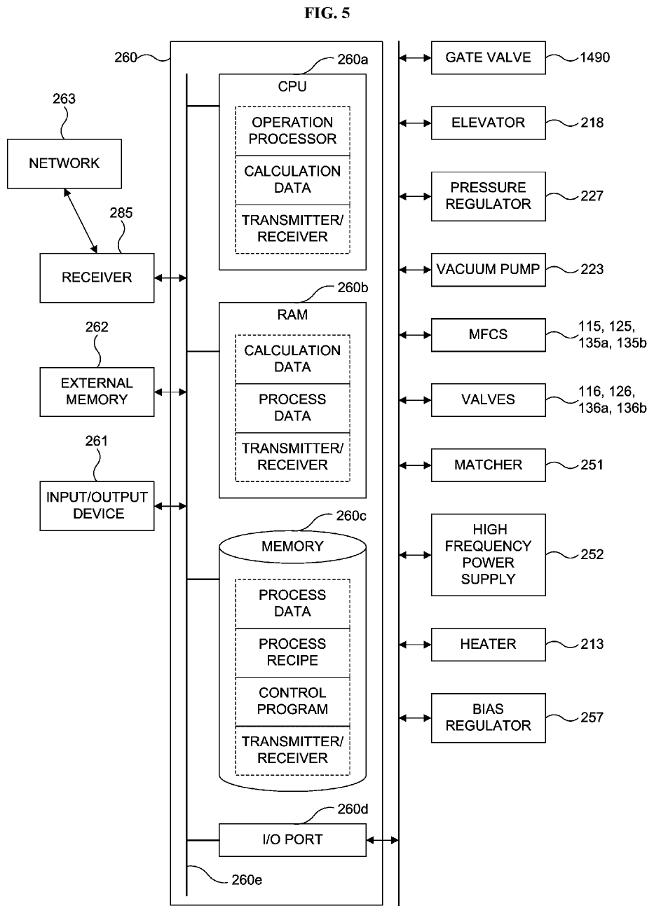

The controller 260 is schematically illustrated in FIG. 5. The controller 260 serving as a control apparatus (or a control structure) is constituted by a computer including a CPU (Central Processing Unit) 260a, a RAM (Random Access Memory) 260b, a memory 260c and an I/O port 260d. The RAM 260b, the memory 260c and the I/O port 260d may exchange data with the CPU 260a through an internal bus 260e. For example, an input/output device 261 constituted by a component such as a touch panel, an external memory 262 and a receiver 285 may be connected to the controller 260.

The memory 260c is configured by a component such as a flash memory and a hard disk drive (HDD). For example, a control program configured to control operations of the substrate processing apparatus 100; a process recipe containing information on process sequences and process conditions of a substrate processing described later; and calculation data and process data generated in a process of setting the process recipe used for processing the wafer 200 may be readably stored in the memory 260c. Further, the process recipe is obtained by combining steps of the substrate processing described later such that the controller 260 can execute the steps to acquire a predetermined result, and functions as a program. Hereafter, the process recipe and the control program may be collectively or individually referred to as a “program.” Thus, in the present specification, the term “program” may refer to the process recipe alone, may refer to the control program alone, or may refer to both of the process recipe and the control program. In addition, the RAM 260b functions as a memory area (work area) where a program or data such as the calculation data and the process data read by the CPU 260a is temporarily stored.

The I/O port 260d is electrically connected to the components such as the gate valve 1490, the elevator 218, the heater 213, the pressure regulator 227, the vacuum pump 223, the matcher 251a, the high frequency power supply 252a, the MFCs 115, 125, 135a and 135b, the valves 116, 126, 136a and 136b and the bias regulator 257.

The CPU 260a serving as an operation processor is configured to read and execute the control program from the memory 260c and to read the process recipe from the memory 260c in accordance with an instruction such as an operation command inputted from the input/output device 261. Further, the CPU 260a is configured to be capable of computing the calculation data by comparing a setting value inputted from the receiver 285 with the process recipe or control data stored in the memory device 260c. In addition, the CPU 260a may select process data (or the process recipe) based on the calculation data. The CPU 260a is configured to be capable of controlling various operations in accordance with the process recipe read from the memory 260c. For example, the CPU 260a is configured to be capable of controlling various operations such as an opening and closing operation of the gate valve 1490, an elevating and lowering operation of the elevator 218, a power supply operation to the heater 213, a pressure adjusting operation of the pressure regulator 227, a turn-on and turn-off operation of the vacuum pump 223, flow rate adjusting operation for various gases by the MFCs 115, 125, 135a and 135b, turn-on and turn-off operations for various gases by the valves 116, 126, 136a and 136b, a power matching control operation of the matcher 251a, a power control operation of the high frequency power supply 252a and an electric potential control operation at the susceptor electrode 256 by the bias regulator 257.

The controller 260 is not limited to a dedicated computer, and the controller 260 may be embodied by a general-purpose computer. For example, the controller 260 according to the present embodiment may be embodied by preparing the external memory 262 (for example, a magnetic tape, a magnetic disk such as a flexible disk and a hard disk, an optical disk such as a CD and a DVD, a magneto-optical disk such as an MO, a semiconductor memory such as a USB memory and a solid state drive (SSD)) in which the program described above is stored, and by installing the program onto the general-purpose computer using the external memory 262. Further, a method of providing the program to the computer is not limited to a case using the external memory 262. For example, the program may be directly provided to the computer by a communication structure such as the receiver 285 and a network 263 (for example, the Internet or a dedicated line) instead of the external memory 262. The memory 260c and the external memory 262 may be embodied by a non-transitory computer-readable recording medium. Hereinafter, the memory 260c and the external memory 262 may be collectively or individually referred to as a “recording medium”. Thus, in the present specification, the term “recording medium” may refer to the memory 260c alone, may refer to the external memory 262 alone, or may refer to both of the memory 260c and the external memory 262.

### (2) Substrate Processing

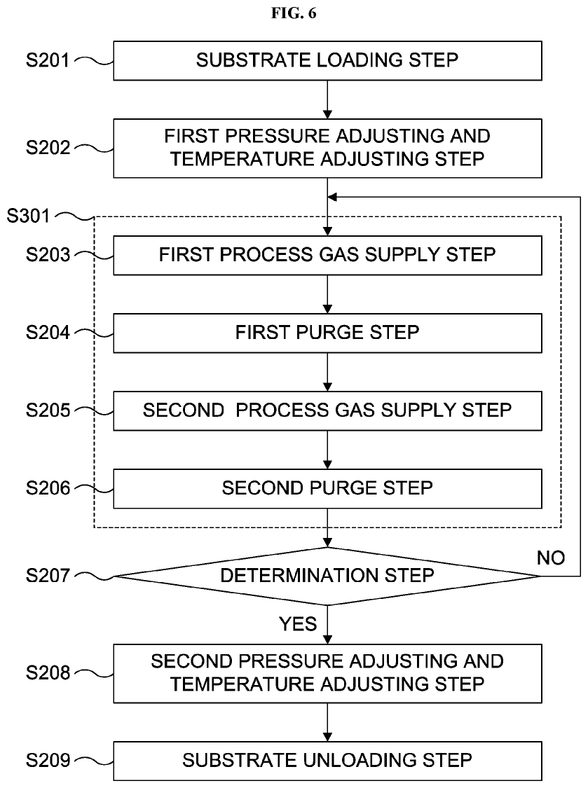

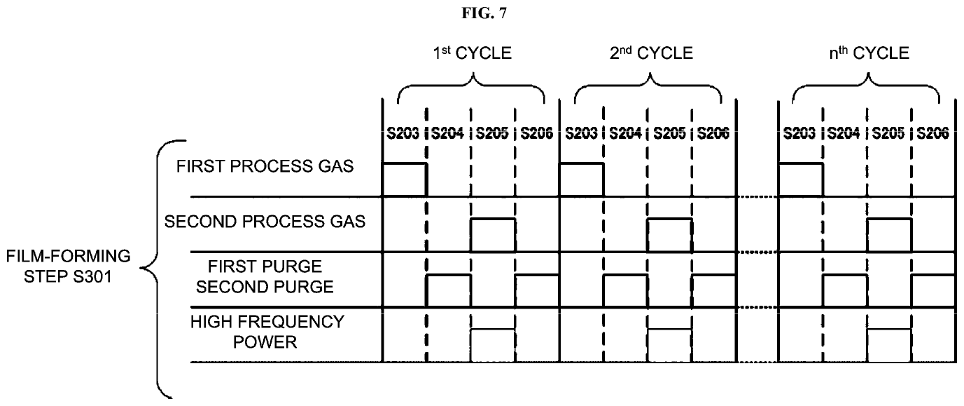

Subsequently, as a part of a process of manufacturing a semiconductor device, the substrate processing (for example, a film-forming process) of forming a film on the substrate (that is, the wafer 200) by using the substrate processing apparatus 100 described above will be described with reference to FIGS. 6 and 7. The substrate processing will be described by way of an example in which a nitride film (which is an insulating film) is formed on the wafer 200. In the following description, the controller 260 controls the operations of the components constituting the substrate processing apparatus 100.

In the present specification, the term “wafer” may refer to “a wafer itself,” or may refer to “a wafer and a stacked structure (aggregated structure) of a predetermined layer (or layers) or a film (or films) formed on a surface of the wafer.” In the present specification, the term “a surface of a wafer” may refer to “a surface of a wafer itself,” or may refer to “a surface of a predetermined layer (or a predetermined film) formed on a wafer.” Thus, in the present specification, “forming a predetermined layer (or a film) on a wafer” may refer to “forming a predetermined layer (or a film) on a surface of a wafer itself,” or may refer to “forming a predetermined layer (or a film) on a surface of another layer (or another film) formed on a wafer.” In the present specification, the terms “substrate” and “wafer” may be used as substantially the same meaning.

An exemplary sequence of the substrate processing of performing the film-forming process on the substrate (that is, the wafer 200) will be described below.

### <Substrate Loading Step S201>

First, in order to perform the film-forming process, the wafer 200 is transferred (or loaded) into the process chamber 201. Specifically, the substrate support 210 is lowered by the elevator 218 such that the lift pins 207 protrude from an upper surface of the substrate support 210 through the through-holes 214. After the inner pressure of the process chamber 201 and an inner pressure of the transfer chamber 203 are adjusted to a predetermined pressure, the gate valve 1490 is opened. Then, the wafer 200 is placed on the lift pins 207 through the substrate loading/unloading port 1480 by using a transfer device (not shown) such as tweezers. After the wafer 200 is placed on the lift pins 207, the gate valve 1490 is closed. Then, the substrate support 210 is elevated to a predetermined position by the elevator 218 such that the wafer 200 is placed on the substrate support 210 from the lift pins 207.

### <First Pressure Adjusting and Temperature Adjusting Step S202>

Subsequently, by opening the valves 136a and 136b, the purge gas whose flow rate is adjusted to a predetermined flow rate by each of the MFCs 135a and 135b is supplied into the process chamber 201, and the inner atmosphere of the process chamber 201 is exhausted through the exhaust port 221 such that the inner pressure of the process chamber 201 reaches and is maintained at a predetermined pressure. In the present step, an opening degree of a valve of the pressure regulator 227 is feedback-controlled based on a pressure value measured by a pressure sensor (not shown). Further, the power applied to the heater 213 is feedback-controlled based on a temperature value detected by a temperature sensor (not shown) such that an inner temperature of the process chamber 201 reaches and is maintained at a predetermined temperature. Specifically, the substrate support 210 is heated in advance by the heater 213. Then, after a temperature of the wafer 200 or the substrate support 210 becomes stable, the substrate support 210 is left in that state for a while. When a gas desorbed from components of the process chamber 201 or moisture is present in the process chamber 201, the gas or the moisture may be effectively removed by purging (or exhausting) the process chamber 201 with the purge gas. Thereby, a preparing step before a film-forming step S301 is now completed. Before setting the inner pressure of the process chamber 201 to the predetermined pressure, the process chamber 201 may be vacuum-exhausted (or evacuated) for once to a vacuum level that can be reached by the vacuum pump 223. In the present step, a temperature of the heater 213 is adjusted from an idling temperature to a constant temperature within a range from 100° C. to 600° C., preferably 150° C. to 500° C., and more preferably 250° C. to 450° C. The voltage is applied to the susceptor electrode 256 by the bias regulator 257 such that an electric potential of the wafer 200 reaches and is maintained at a predetermined electric potential.

### <Film-Forming Step S301>

After the wafer 200 is placed on the substrate support 210 and the inner atmosphere of the process chamber 201 is stabilized, the film forming step S301 is continued. The present embodiment will be described by way of an example in which the nitride film serving as the film is formed on the wafer 200. Hereinafter, an example in which a silicon nitride film (SiN film) serving as the nitride film is formed will be described. The film forming step S301 will be described in detail with reference to FIGS. 6 and 7. In the film-forming step S301, a first process gas supply step S203, a first purge step S204, a second process gas supply step S205, a second purge step S206 and a determination step S207 described below are performed.

### <First Process Gas Supply Step S203>

In the first process gas supply step S203, a source gas serving as the first process gas is supplied into the process chamber 201 through the first process gas supplier. As the source gas, for example, a silane-based gas containing silicon (Si) serving as a main element (primary element) constituting the film formed on the wafer 200 may be used. As the silane-based gas, for example, a gas containing silicon and a halogen element, that is, a halosilane-based gas may be used. The halogen element includes an element such as chlorine (Cl), fluorine (F), bromine (Br) and iodine (I). As the halosilane-based gas, for example, a chlorosilane-based gas containing silicon and chlorine may be used.

In the first process gas supply step S203, specifically, the valve 116 is opened, and a flow rate of the first process gas supplied from the first process gas supply source is adjusted by the MFC 115. The first process gas whose flow rate is adjusted is then supplied to the substrate processing apparatus 100. The first process gas whose flow rate is adjusted passes through the first buffer chamber 232a of the first gas distributor 235a, and is supplied to the process chamber 201 in a depressurized state through the plurality of first dispersion holes 234a. Further, the exhauster continuously exhausts the process chamber 201 and the pressure regulator 227 is controlled such that the inner pressure of the process chamber 201 reaches and is maintained at a first pressure within a predetermined pressure range. With the inner pressure of the process chamber 201 is maintained at the first pressure within the predetermined pressure range, the first process gas is supplied into the process chamber 201 at the first pressure. For example, the first pressure may be set to a pressure within a range from 100 Pa to 10 kPa. By supplying the first process gas in a manner described above, a silicon-containing layer serving as a first layer is formed on the wafer 200. According to the present embodiment, the silicon-containing layer refers to a layer containing silicon (Si) or a layer containing silicon and chlorine (Cl).

### <First Purge Step S204>

In the first purge step S204, after the silicon-containing layer is formed on the wafer 200, the valve 116 of the first process gas supply pipe 113 is closed to stop a supply of the first process gas. By continuously exhausting the process chamber 201 by the exhauster (that is, the vacuum pump 223) and by stopping the supply of the first process gas, it is possible to remove (or exhaust) a residual gas in the process chamber 201 such as the first process gas present in the process chamber 201 and reaction by-products and the process gas remaining in the first buffer chamber 232a. That is, the process chamber 201 is purged by using the vacuum pump 223. In the first purge step S204, by opening the valve 136a of the purge gas supplier (that is, the first purge gas supplier) and by supplying the purge gas whose flow rate is adjusted by the MFC 135a, it is possible to push out the residual gas in the first buffer chamber 232a, and it is also possible to increase an efficiency of removing a residual gas on the wafer 200 such as the first process gas and the reaction by-products. In the first purge step S204, the second purge gas supplier may be used in combination with the first purge gas supplier, or a supply of the purge gas and a stop of the supply of the purge gas may be performed alternately.

After a predetermined time has elapsed, the valve 136a is closed to stop the supply of the purge gas. However, the purge gas may be continuously supplied by opening the valve 136a. By continuously supplying the purge gas to the first buffer chamber 232a, it is possible to prevent (or suppress) the process gas of another step from entering the first buffer chamber 232a in another step. In the first purge step S204, the flow rate of the purge gas supplied into the process chamber 201 or the first buffer chamber 232a may not be a large flow rate. For example, the process chamber 201 may be purged by supplying the purge gas of an amount substantially equal to a volume of the process chamber 201 such that a subsequent step (that is, the second process gas supply step S205) will not be adversely affected. By not completely purging the process chamber 201 as described above, it is possible to shorten a purge time for purging the process chamber 201, and it is also possible to improve a manufacturing throughput. In addition, it is possible to reduce a consumption of the purge gas to the minimum.

In the first purge step S204, a temperature of the heater 213 is set (adjusted) to substantially the same temperature as that of the heater 213 in the first process gas supply step S203 of supplying the first process gas to the wafer 200. For example, the flow rate of the purge gas supplied through the purge gas supplier (that is, the first purge gas supplier) is set to a flow rate within a range from 100 sccm to 10,000 sccm.

### <Second Process Gas Supply Step S205>

In the second process gas supply step S205, the valve 126 of the second process gas supplier is opened, and the reactive gas serving as the second process gas is supplied into the process chamber 201 in a depressurized state through the second buffer chamber 232b and the plurality of second dispersion holes 234b of the second gas distributor 235b. As the reactive gas, for example, a gas containing nitrogen (N) and hydrogen (H) may be used. Hereinafter, the gas containing nitrogen and hydrogen may also be referred to as an “N- and H-containing gas.” In the second process gas supply step S205, the exhauster continuously exhausts the process chamber 201, a flow rate of the second process gas is adjusted by the MFC 125 to a predetermined flow rate (for example, within a range from 100 sccm to 5,000 sccm), and the pressure regulator 227 is controlled such that the inner pressure of the process chamber 201 reaches and is maintained at a second pressure (for example, within a predetermined pressure range from 1 Pa to 200 Pa).

Further, in the second process gas supply step S205, the high frequency power is supplied from the high frequency power supply 252a to the coil 253a of the plasma generator 270 through the matcher 251a. In FIG. 7, a supply of the high frequency power is started simultaneously with a supply of the second process gas. However, the supply of the high frequency power may be started before the supply of the second process gas or the high frequency power may be continued to be supplied thereafter. By supplying the high frequency power, it is possible to generate the plasma of the second process gas on the wafer 200.

The N- and H-containing gas (which serves as the second process gas (reactive gas)) is excited into a plasma state. Thereby, the active species such as NHₓ* (where x is an integer of 1 to 3) can be generated and supplied to the wafer 200 (plasma-excited N- and H-containing gas supply). Thereby, the N- and H-containing gas containing the active species such as NH*, NH₂* and NH₃* is supplied onto the wafer 200. In the present specification, the symbol “*” refers to a radical. The same also applies to the following descriptions. The active species of the N- and H-containing gas supplied to the wafer 200 reacts with at least part of the silicon-containing layer to form a silicon nitride layer (also referred to as an “SiN layer”) serving as a layer containing silicon (Si) and nitrogen (N). That is, by supplying the active species of the activated N- and H-containing gas to the silicon-containing layer, it is possible to perform a nitridation process on the silicon-containing layer at a low temperature. Further, when the active species of the activated N- and H-containing gas is supplied to the silicon-containing layer, it is also possible to perform a modification process on the silicon-containing layer such as a recovery of defects in a molecular bond and a desorption of impurities.

In the second process gas supply step S205, the gap distance 273 is adjusted by the micrometer 259 such that the plasma distribution in the process chamber 201 is in a desired state. Specifically, for example, by rotating the micrometer 259, the gap distance 273 is adjusted to an optimum distance such that the plasma distribution in the process chamber 201 is in a desired state in the horizontal direction on the wafer 200. The optimum distance may be appropriately set in accordance with parameters such as an apparatus specification and various process conditions. That is, the optimum distance is not limited to a specific value.

In a manner described above, in the plasma generator 270, by adjusting the power supplied from the high frequency power supply 252a to the coil 253a and the gap distance 273, it is possible to adjust the plasma distribution according to the surface area of the wafer 200, and it is also possible to supply the active species of the activated N- and H-containing gas to the wafer 200 in a similar distribution. When the active species of the activated N- and H-containing gas (also referred to as an “active species containing nitrogen and hydrogen”) is insufficient with respect to the wafer 200, by shortening the gap distance 273, it is possible to increase the generation amount of the plasma, and it is also possible to increase the active species containing nitrogen and hydrogen. Therefore, even when the wafer 200 whose surface area involves a large consumption of the active species is used, by adjusting the power supplied from the high frequency power supply 252a to the coil 253a and the gap distance 273, it is possible to sufficiently supply the active species of the activated N- and H-containing gas. As a result, it is possible to uniformly form the SiN layer (SiN film) on the surface of the wafer 200.

According to the present embodiment, for example, the power supplied from the high frequency power supply 252a to the plasma generator 270 is set to a power within a range from 300 W to 1,500 W, preferably from 500 W to 1,000 W. When the power is less than 300 W, the plasma of a CCP (Capacitively Coupled Plasma) mode becomes dominant, so an amount of the active species generated by the plasma is extremely low. As a result, a rate (or a speed) of processing the wafer is greatly reduced. Further, when the power exceeds 1,000 W, the plasma begins to strongly sputter against an inner wall of a reaction chamber (that is, the process vessel 202) made of quartz, so a material such as silicon (Si) and oxygen (O) which is undesirable for a film on the wafer 200 (that is, a film other than the SiN film) may be supplied.

In addition, a plasma process time is set to a time duration within a range from 10 seconds to 300 seconds, preferably from 30 seconds to 120 seconds. When the plasma process time is less than 10 seconds, it may not be possible to obtain a sufficient thickness of the film (that is, the SiN layer). On the other hand, when the plasma process time exceeds 300 seconds, a uniformity of the film may be adversely affected on the surface of the substrate (that is, the wafer 200) or on stepped portions on the substrate. Further, the substrate itself may be damaged.

For example, by adjusting the electric potential of the susceptor electrode 256 provided in the substrate mounting table 212 by the bias regulator 257, it is possible to control an amount of plasma charged particles supplied to the wafer 200. For example, when a step processing is performed on the surface of the wafer 200, by suppressing the amount of the plasma charged particles supplied to the wafer 200, it is possible to effectively improve a film coverage ratio of the film-forming process. Further, for example, by adjusting conditions such as the inner pressure of the process chamber 201, the flow rate of the second process gas adjusted by the MFC 125 and the temperature of the wafer 200 adjusted by the heater 213, depending on results of adjusting the conditions described above, it is possible to perform the nitridation process or the modification process with a predetermined distribution, a predetermined depth and a predetermined nitrogen composition ratio with respect to the silicon-containing layer.

After a predetermined time has elapsed from a start of the second process gas supply step S205, the valve 126 of the second process gas supplier is closed to stop the supply of the second process gas. In the second process gas supply step S205, the temperature of the heater 213 is set (adjusted) to substantially the same temperature as that of the heater 213 in the first process gas supply step S203 of supplying the first process gas to the wafer 200.

### <Second Purge Step S206>

In the second purge step S206, after a nitrogen-containing layer such as the SiN layer is formed on the wafer 200, the valve 126 of the second process gas supply pipe 123 is closed to stop the supply of the second process gas. By continuously exhausting the process chamber 201 by the exhauster (that is, the vacuum pump 223) and by stopping the supply of the second process gas, it is possible to remove (or exhaust) a residual gas in the process chamber 201 such as the second process gas present in the process chamber 201 and reaction by-products and the process gas remaining in the second buffer chamber 232b. That is, the process chamber 201 is purged by using the vacuum pump 223. In the second purge step S206, by opening the valve 136b of the second purge gas supplier and by supplying the purge gas whose flow rate is adjusted by the MFC 135b, it is possible to push out the residual gas in the second buffer chamber 232b, and it is also possible to increase an efficiency of removing the residual gas on the wafer 200 such as the second process gas and the reaction by-products. In the second purge step S206, the first purge gas supplier may be used in combination with the second purge gas supplier, or the supply of the purge gas and the stop of the supply of the purge gas may be performed alternately.

After a predetermined time has elapsed, the valve 136b is closed to stop the supply of the purge gas. However, the purge gas may be continuously supplied by opening the valve 136b. By continuously supplying the purge gas to the second buffer chamber 232b, it is possible to prevent (or suppress) the process gas of another step from entering the second buffer chamber 232b in another step. In the second purge step S206, the flow rate of the purge gas supplied into the process chamber 201 or the second buffer chamber 232b may not be a large flow rate. For example, the process chamber 201 may be purged by supplying the purge gas of the amount substantially equal to the volume of the process chamber 201 such that a subsequent step (that is, the first process gas supply step S203) will not be adversely affected. By not completely purging the process chamber 201 as described above, it is possible to shorten the purge time for purging the process chamber 201, and it is also possible to improve the manufacturing throughput. In addition, it is possible to reduce the consumption of the purge gas to the minimum.

In the second purge step S206, the temperature of the heater 213 is set (adjusted) to substantially the same temperature as that of the heater 213 in the second process gas supply step S205 of supplying the second process gas to the wafer 200. For example, the flow rate of the purge gas supplied through the purge gas supplier (that is, the second purge gas supplier) is set to a flow rate within a range from 100 sccm to 10,000 sccm.

### <Determination Step S207>

After the second purge step S206 is completed, the controller 260 determines whether a cycle (of the film-forming step S301) including the step S203 through the step S206 is performed a predetermined number of times (n times). That is, the controller 260 determines whether a film (that is, the SiN film) of a desired thickness is formed on the wafer 200. It is possible to form the SiN film on the wafer 200 by performing the cycle including the step S203 through the step S206 at least once in the film-forming step S301. It is preferable that the cycle is performed a plurality of times until the SiN film of the desired thickness is formed on the wafer 200.

When the controller 260 determines, in the determination step S207, that the cycle is not performed the predetermined number of times (“NO” in FIG. 6), the cycle including the step S203 through the step S206 of the film-forming step S301 is repeatedly performed. When the controller 260 determines, in the determination step S207, that the cycle is performed the predetermined number of times (“YES” in FIG. 6), the film-forming step S301 is terminated.

### <Second Pressure Adjusting and Temperature Adjusting Step S208>

After the film-forming step S301 is completed, by opening the valves 136a and 136b, the purge gas such as N₂ gas whose flow rate is adjusted to a predetermined flow rate by each of the MFCs 135a and 135b is supplied into the process chamber 201 such that the inner pressure of the process chamber 201 reaches and is maintained at a predetermined pressure. In the present step, the pressure regulator 227 is controlled based on a pressure value measured by the pressure sensor (not shown). Further, the power applied to the heater 213 is controlled based on a temperature value detected by the temperature sensor (not shown) such that the inner temperature of the process chamber 201 reaches and is maintained at a predetermined temperature. In the present step, for example, the inner pressure of the process chamber 201 may be set to substantially the same pressure as that of the process chamber 201 when the gate valve 1490 is opened in the first pressure adjusting and temperature adjusting step S202, and the temperature of the heater 213 may be set to substantially the same temperature as that of the heater 213 in an idling state (that is, the idling temperature described above). Alternatively, when a subsequent wafer 200 is continuously processed under the same temperature conditions, the temperature of the heater 213 may be maintained.

### <Substrate Unloading Step S209>

Subsequently, the substrate support 210 is lowered by the elevator 218 such that the lift pins 207 protrude from the upper surface of the substrate support 210 through the through-holes 214 and the wafer 200 is placed on the lift pins 207. The gate valve 1490 is opened, and the wafer 200 is transferred (or unloaded) out of the transfer chamber 203 through the substrate loading/unloading port 1480 using the transfer device (not shown) such as the tweezers. Then, the gate valve 1490 is closed.

By performing the substrate processing as described above, it is possible to obtain the wafer 200 with the SiN film of a predetermined thickness formed on the surface thereof.

### (3) Effects According to Present Embodiment

According to the present embodiment, it is possible to obtain one or more of the following effects.

(a) According to the present embodiment, by adjusting the power of the high frequency power supply 252a and adjusting the gap distance 273 by rotating the micrometer 259, it is possible to control (adjust) the plasma distribution of the second process gas generated in the process chamber 201 by the plasma generator 270. Therefore, for example, by controlling the plasma distribution in the process chamber 201 according to the surface area of the wafer 200, it is possible to supply the active species of the second process gas with a similar distribution. Therefore, even when the wafer 200 whose surface area involves a large consumption of the active species is used, it is possible to uniformly form the film on the surface of the wafer 200.

(b) According to the present embodiment, the insulator 271a is provided with a portion of the hemispherical shape or the semi-spheroid shape so as to protrude toward the inner space of the process chamber 201. Therefore, by ensuring the surface area of the coil 253a facing the insulator 271a, it is possible to improve the plasma generation efficiency. Then, by adjusting the power supplied from the high frequency power supply 252a to the coil 253a and adjusting the gap distance 273, it is possible to reliably control the plasma distribution. In other words, the present embodiment is extremely useful for controlling the plasma distribution.

(c) According to the present embodiment, the coil 253a is of the spiral shape with at least 0.4 winding turn, and the side portion of the coil 253a is provided along the curved surface of the insulator 271a. In this respect as well, by ensuring the surface area of the coil 253a (of a planar shape) whose side portion is provided along the curved surface of the insulator 271a, it is also possible to improve the plasma generation efficiency. Then, by adjusting the power supplied from the high frequency power supply 252a to the coil 253a and adjusting the gap distance 273, it is also possible to reliably control the plasma distribution. In other words, the present embodiment is extremely useful for controlling the plasma distribution.

### Second Embodiment of Present Disclosure

Subsequently, a second embodiment according to the technique of the present disclosure will be described with reference to the drawings.

A substrate processing apparatus 100A of the second embodiment of the present disclosure is different from the substrate processing apparatus 100 of the first embodiment in a configuration of a plasma generator. Since other configurations of the second embodiment are substantially the same as those of the first embodiment, the plasma generator of the second embodiment will be mainly described.

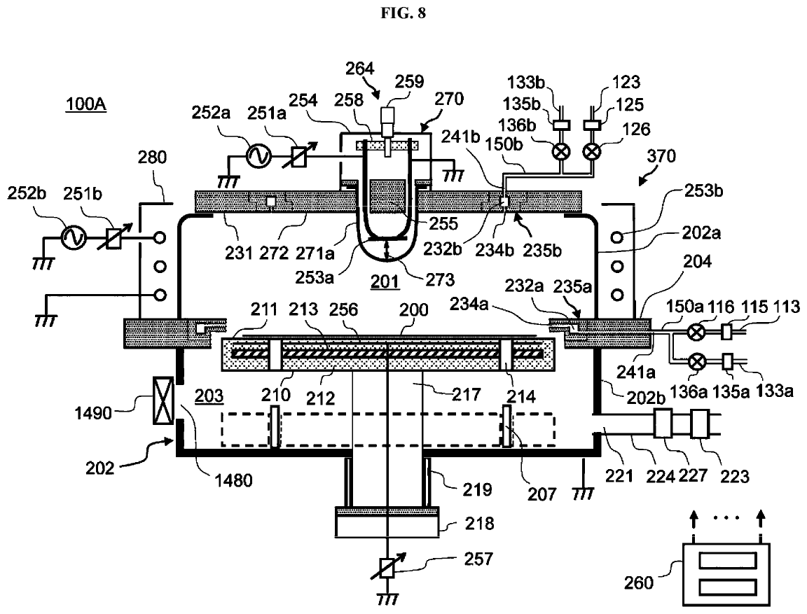

As shown in FIG. 8, the substrate processing apparatus 100A is provided with: a plasma generator 270 arranged at the upper portion of the upper vessel 202a and partially protruding into the process chamber 201; and a coil 253b serving as a second coil (another coil) arranged outside the upper vessel 202a. The plasma generator 270 according to the present embodiment is constituted by: the insulator 271a fixed to the lid 231; the coil 253a arranged in the insulator 271a; the first electromagnetic wave shield 254 (which is arranged above the coil 253a) and the second electromagnetic wave shield 255 provided to cover the coil 253a; the reinforcing structure (or the fixing structure) 258 reinforced by fixing the both ends of the coil 253a with the insulating material such as the resin; and the micrometer 259 (which is the moving structure or the mover capable of vertically moving the coil 253a) including the shaft fixed to the first electromagnetic wave shield 254 and moving vertically while rotating.

The coil 253b is arranged inside the shield plate 280 of a cylindrical shape and outside the upper vessel 202a. Further, the coil 253b constitutes a part of a plasma generator (plasma generation apparatus) 370 serving as a second plasma generator configured to generate the plasma in the process chamber 201. The coil 253b is configured by using a conductive metal pipe wound in a spiral shape with 1 winding turn to 10 winding turns around an outer periphery of the upper vessel 202a. Further, the coil 253b is shielded by being surrounded by the shield plate 280 of a cylindrical shape made of a conductive metal plate.

The first end (one end) of the coil 253a and a first end (one end) of the coil 253b are connected to the matcher 251a and a matcher 251b and the high frequency power supply 252a and a high frequency power supply 252b, respectively, and the second end (the other end) of the coil 253a (and a second end of the coil 253b) is connected to the ground. The first electromagnetic wave shield 254, the second electromagnetic wave shield 255 and the shield plate 280 are also connected to the ground of each of the plasma generators 270 and 370. The high frequency power from the high frequency power supply 252a is supplied (or applied) between the first end of the coil 253a connected to the matcher 251a and the ground to which the second end of the coil 253a, the first electromagnetic wave shield 254 and the second electromagnetic wave shield 255 are connected. Further, a high frequency power from the high frequency power supply 252b is supplied (or applied) between the first end of the coil 253b connected to the matcher 251b and the ground to which the second end of the coil 253b and the shield plate 280 are connected.

According to a combination of the plasma generator 270 and the plasma generator 370 configured as described above, when the process gas (in particular, the reactive gas serving as the second process gas) is supplied to the process chamber 201, the process gas is induced by the alternating magnetic field created by the coil 253a and the coil 253b, and thereby, the inductively coupled plasma (abbreviated as “ICP”) is generated. That is, when the plasma is generated by using the combination of the plasma generator 270 and the plasma generator 370, it is possible to greatly improve the amount of the active species generated in the second process gas (that is, the reactive gas) as compared with a case where the plasma generator 270 alone is used to generate the plasma in the first embodiment. Further, it is possible to more precisely adjust (control) the plasma distribution.

By adjusting the power supplied from the high frequency power supply 252a to the coil 253a and adjusting the gap distance 273 and by adjusting the power supplied from the high frequency power supply 252b to the coil 253b, it is possible to more precisely adjust (control) the plasma distribution according to the surface area of the wafer 200. Thereby, it is possible to supply the active species of the activated N- and H-containing gas with a similar distribution. Therefore, even when the wafer 200 whose surface area involves a large consumption of the active species is used, it is possible to sufficiently supply the active species of the activated N- and H-containing gas. That is, the present embodiment is extremely effective when more uniformly forming the film on the surface of the wafer 200.

The present embodiment is described by way of the example in which the two plasma generators 270 and 370 are provided. However, the present embodiment is not limited thereto. For example, depending on the plasma distribution in the process chamber 201, three or more plasma generators may be provided, the plasma generators may be unevenly distributed, or a plurality of types including combinations thereof may be provided.

### Third Embodiment of Present Disclosure

Subsequently, a third embodiment according to the technique of the present disclosure will be described with reference to the drawings.

A substrate processing apparatus 100B of the third embodiment of the present disclosure is different from the substrate processing apparatus 100 of the first embodiment in an entire hardware configuration of the substrate processing apparatus 100B. That is, the substrate processing apparatus 100B according to the third embodiment of the present disclosure is obtained by introducing a plasma generator into a so-called vertical type substrate processing apparatus instead of the single wafer type substrate processing apparatus described above.

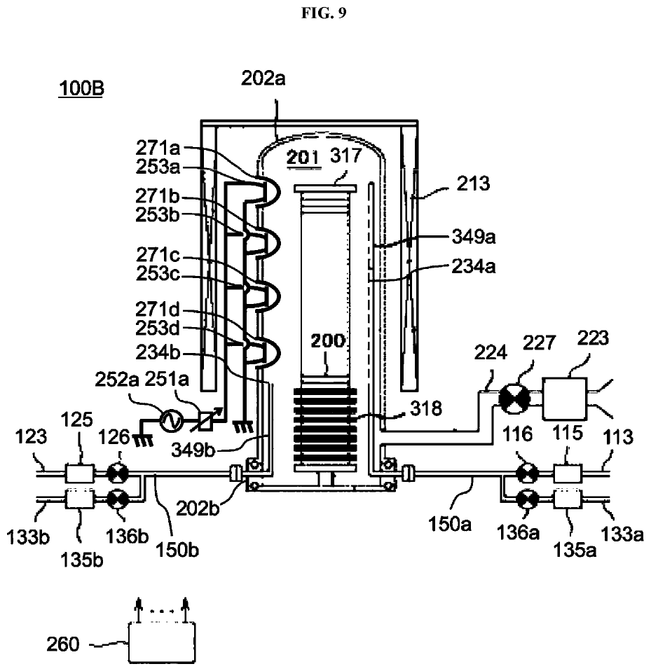

As shown in FIG. 9, in the substrate processing apparatus 100B, a boat 317 capable of stacking a plurality of wafers including the wafer 200; and a heat insulating plate 318 capable of suppressing a heat escape to a lower portion of the process chamber 201 are additionally provided. Further, in the substrate processing apparatus 100B, instead of the first gas distributor 235a and the second gas distributor 235b of the first embodiment, a gas nozzle 349a connected to the first gas supply pipe 150a and a gas pipe 349b connected to the second gas supply pipe 150b are provided. Since other configurations of the third embodiment such as a configuration of supplying the gas and a configuration of exhausting the gas are substantially the same as those of the first embodiment, the plasma generator of the third embodiment will be mainly described.

In the substrate processing apparatus 100B, insulators 271a, 271b, 271c and 271d of a hemispherical shape welded to a side surface of the upper vessel 202a at regular intervals in the vertical direction are provided so as to protrude toward the inner space of the process chamber 201. Coils 253a, 253b, 253c and 253d configured by using conductive metal pipes and of a spiral shape with 0.9 winding turn are inserted into the insulators 271a, 271b, 271c and 271d, respectively. The high frequency power from the high frequency power supply 252a is supplied (or applied) between a first end (one end) of each of the coils 253a, 253b, 253c and 253d connected in parallel to the matcher 251a and the ground to which a second end (the other end) of each of the coils 253a, 253b, 253c and 253d is connected.

In the substrate processing apparatus 100B described above, when the reactive gas is supplied to the process chamber 201, the reactive gas is induced by an alternating magnetic field created by the coils 253a, 253b, 253c and 253d, and thereby, the inductively coupled plasma (ICP) is generated. When generating the ICP, by fine-tuning at least one of distances from the insulators 271a, 271b, 271c and 271d to the coils 253a, 253b, 253c and 253d by using a component such as a fixing jig, it is possible to control the plasma distribution in the vertical direction within the process chamber 201.

The shape and the number of the insulators and the shape and the number of the coils are not limited to those described above. For example, based on the plasma distribution, various combinations of the shape and the number of the insulators and the shape and the number of the coils may be performed. Thereby, it is possible to greatly improve the amount of the active species generated in the reactive gas.

### Other Embodiments of Present Disclosure

While the technique of the present disclosure is described in detail by way of the first embodiment, the second embodiment and the third embodiment described above, the technique of the present disclosure is not limited thereto. The technique of the present disclosure may be modified in various ways without departing from the scope thereof.

For example, the embodiments described above are described by way of an example in which the reactive gas is supplied after the source gas is supplied and the film is formed by alternately supplying the source gas and the reactive gas. However, the technique of the present disclosure is not limited thereto. For example, the technique of the present disclosure may also be applied when a supply order of the source gas and the reactive gas is changed or when a supply method in which a supply timing of the source gas and a supply timing of the reactive gas overlap at least partially is used. By changing the supply order of the process gas such as the source gas and the reactive gas or by using the supply method described above, it is possible to change a quality or a composition of the film formed by performing the substrate processing.

For example, the embodiments described above are described by way of an example in which the silicon nitride film (SiN film) is formed on the wafer 200. However, the technique of the present disclosure is not limited thereto. For example, the technique of the present disclosure may also be applied to form a film containing oxygen or a film containing carbon by using different gases. For example, the technique of the present disclosure may also be preferably applied to form, on the wafer 200, a silicon-based oxide film or a silicon-based carbide film such as a silicon oxide film (SiO film), a silicon carbide film (SiC film), a silicon oxycarbide film (SiOC film), a silicon oxycarbonitride film (SiOCN film) and a silicon oxynitride film (SiON film).

For example, the chlorosilane-based gas such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas, hexachlorodisilane (Si₂Cl₆, abbreviated as HCDS) gas and octachlorotrisilane (Si₃Cl₈, abbreviated as OCTS) gas may be preferably used as the source gas. For example, an aminosilane source gas such as tetrakis(dimethylamino) silane (Si[N(CH₃)₂]₄, abbreviated as 4DMAS) gas, tris(dimethylamino) silane (Si[N(CH₃)₂]₃H, abbreviated as 3DMAS) gas, bis(dimethylamino) silane (Si[N(CH₃)₂]₂H₂, abbreviated as BDMAS), bis(diethylamino) silane (Si[N(C₂H₅)₂]₂H₂, abbreviated as BDEAS) gas, bis(tertiarybutylamino) silane (SiH₂[NH(C₄H9)]2, abbreviated as BTBAS) gas, dimethylaminosilane (DMAS) gas, diethylaminosilane (DEAS) gas, dipropylaminosilane (DPAS) gas, diisopropylaminosilane (DIPAS) gas, butylaminosilane (BAS) gas and hexamethyldisilazane (HMDS) gas may be preferably used as the source gas. For example, an organic silane source gas such as monomethylsilane (Si(CH₃)H₃, abbreviated as MMS) gas, dimethylsilane (Si(CH₃)₂H₂, abbreviated as DMS) gas, trimethylsilane (Si(CH₃)₃H, abbreviated as 3MS) gas, tetramethylsilane (Si(CH₃)₄, abbreviated as 4MS) gas and 1,4 disilabutane (abbreviated as 1,4DSB) gas may be preferably used as the source gas. For example, an inorganic silane source gas free of a halogen group such as monosilane (SiH₄, abbreviated as MS) gas, disilane (Si₂H₆, abbreviated as DS) gas and trisilane (Si₃H₈, abbreviated as TS) gas may be preferably used as the source gas. For example, an aminosilane source material of the aminosilane source gas refers to a silane source material containing an amino group, also refers to a silane source material containing an alkyl group such as a methyl group, an ethyl group and a butyl group, and also refers to a source material containing at least silicon (Si), nitrogen (N) and carbon (C). That is, the aminosilane source material in the present specification may refer to an organic source material or an organic aminosilane source material.

For example, a nitrogen-containing gas such as nitrogen gas, diazene (N₂H2) gas, ammonia (NH₃) gas, hydrazine (N₂H₄) gas and N₃H₈ gas may be preferably used as the N- and H-containing gas serving as the reactive gas. As the N- and H-containing gas, one or more of the gases exemplified above may be used. Further, for example, an amine-based gas may also be used as the nitrogen-containing gas. The amine-based gas refers to a gas containing an amine group, and also refers to a gas containing at least carbon (C), nitrogen (N) and hydrogen (H). The amine-based gas contains an amine such as ethylamine, methylamine, propylamine, isopropylamine, butylamine and isobutylamine. In the present specification, the amine collectively or individually refers to compounds in which a hydrogen atom of the ammonia (NH₃) is substituted with a hydrocarbon group such as an alkyl group. That is, the amine contains the hydrocarbon group such as the alkyl group. Since the amine-based gas does not contain silicon (Si), the amine-based gas may also be referred to as a “silicon-free gas.” Further, since the amine-based gas does not contain silicon (Si) and a metal, the amine-based gas may also be referred to as a “gas free of silicon and free of metal.” For example, an ethylamine-based gas such as tricthylamine ((C₂H₅)₃N, abbreviated as TEA), diethylamine ((C₂H₅)₂NH, abbreviated as DEA) and monocthylamine (C₂H₅NH₂, abbreviated as MEA) may be preferably used as the amine-based gas. For example, a methylamine-based gas such as trimethylamine ((CH₃)₃N, abbreviated as TMA), dimethylamine ((CH₃)₂NH, abbreviated as DMA) and monomethylamine (CH₃NH₂, abbreviated as MMA) may be preferably used as the amine-based gas. For example, a propylamine-based gas such as tripropylamine ((C₃H₇)₃N, abbreviated as TPA), dipropylamine ((C₃H₇)₂NH, abbreviated as DPA) and monopropylamine (C₃H₇NH₂, abbreviated as MPA) may be preferably used as the amine-based gas. For example, an isopropylamine-based gas such as triisopropylamine ([(CH₃)₂CH]₃N, abbreviated as TIPA), diisopropylamine ([(CH₃)₂CH]₂NH, abbreviated as DIPA) and monoisopropylamine ((CH₃)₂CHNH₂, abbreviated as MIPA) may be preferably used as the amine-based gas. For example, a butylamine-based gas such as tributylamine ((C₄H₉)₃N, abbreviated as TBA), dibutylamine ((C₄H₉)₂NH, abbreviated as DBA) and monobutylamine (C₄H₉NH₂, abbreviated as MBA) may be preferably used as the amine-based gas. For example, an isobutylamine-based gas such as triisobutylamine ([(CH₃)₂CHCH₂]₃N, abbreviated as TIBA), diisobutylamine ([(CH₃)₂CHCH₂]₂NH, abbreviated as DIBA) and monoisobutylamine ((CH₃)₂CHCH₂NH₂, abbreviated as MIBA) may be preferably used as the amine-based gas. That is, for example, at least one gas selected from the group of (C₂H₅)ₓNH₃₋ₓ, (CH₃)ₓNH₃₋ₓ, (C₃H₇)ₓNH₃₋ₓ, [(CH₃)₂CH]ₓNH₃₋ₓ, (C₄H₉)ₓNH₃₋ₓ and [(CH₃)₂CHCH₂]ₓNH₃₋ₓ (wherein x is an integer from 1 to 3) may be preferably used as the amine-based gas. The amine-based gas acts as a nitrogen source when forming the film such as the SiN film, the SiCN film and the SiOCN film, and also acts as a carbon source. By using the amine-based gas as the nitrogen-containing gas, it is possible to control carbon component in the film such that an amount of the carbon components in the film is increased. For example, an oxidizing agent (or an oxidizing gas), that is, an oxygen-containing gas serving as an oxygen source may also be used as the reactive gas. For example, the oxygen-containing gas such as oxygen (O₂) gas, water vapor (H₂O gas), nitrous oxide (N₂O) gas, nitric oxide (NO) gas, nitrogen dioxide (NO₂) gas, ozone (O₃) gas, hydrogen peroxide (H₂O₂) gas, carbon monoxide (CO) gas and carbon dioxide (CO₂) gas may also be preferably used as the reactive gas.

As the purge gas, for example, an inert gas may be used. In addition, as the inert gas used as the purge gas, for example, nitrogen (N₂) gas or a rare gas such as argon (Ar) gas, helium (He) gas, neon (Ne) gas and xenon (Xe) gas may be used. As the purge gas, one or more of the gases exemplified above may be used.

The technique of the present disclosure may also be preferably applied to form a metalloid film containing a metalloid element or a metal-based film containing a metal element. Process sequences and process conditions of a film-forming process of forming the metalloid film or the metal-based film may be substantially the same as those of the film-forming process according to the embodiments or modified examples described above. Even in such a case, it is possible to obtain substantially the same effects as the embodiments described above. The technique of the present disclosure may also be applied to form, on the wafer 200, a metal-based oxide film or a metal-based nitride film containing a metal element such as titanium (Ti), zirconium (Zr), hafnium (Hf), tantalum (Ta), niobium (Nb), aluminum (Al), molybdenum (Mo) and tungsten (W). That is, the technique of the present disclosure may also be applied to form, on the wafer 200, a film such as a TiO film, a TiOC film, a TiOCN film, a TiON film, a TiN film, a TiCN film, a ZrO film, a ZrOC film, a ZrOCN film, a ZrON film, a ZrN film, a ZrCN film, a HfO film, a HfOC film, a HfOCN film, a HfON film, a HIN film, a HfCN film, a TaO film, a TaOC film, a TaOCN film, a TaON film, a TaN film, a TaCN film, a NbO film, a NbOC film, a NbOCN film, a NbON film, a NbN film, a NbCN film, an AlO film, an AlOC film, an AlOCN film, an AlON film, an AlN film, an AlCN film, a MoO film, a MoOC film, a MoOCN film, a MOON film, a MON film, a MoCN film, a WO film, a WOC film, a WOCN film, a WON film, a WN film and a WCN film. For example, various gases such as tetrakis(dimethylamino) titanium (Ti[N(CH₃)₂]₄, abbreviated as TDMAT) gas, tetrakis(cthylmethylamino) hafnium (Hf[N(C₂H₅)(CH₃)]₄, abbreviated as TEMAH) gas, tetrakis(ethylmethylamino) zirconium (Zr[N(C₂H₅)(CH₃)]₄, abbreviated as TEMAZ) gas, trimethylaluminum (Al(CH₃)₃, abbreviated as TMA) gas, titanium tetrachloride (TiCl₄) gas and hafnium tetrachloride (HfCl₄) gas may be used as the source gas to form the metal-based oxide film or the metal-based nitride film described above.

The embodiments described above are described by way of an example in which the film-forming process is performed. However, the technique of the present disclosure is not limited thereto. For example, the technique of the present disclosure may also be applied to other processes instead of the film-forming process. That is, the technique of the present disclosure may also be applied to a process using the plasma such as a diffusion process, an oxidation process, a nitridation process, an oxynitridation process, a reduction process, an oxidation-reduction process, an etching process and a heating process. For example, the technique of the present disclosure may also be applied to a plasma oxidation process, a plasma nitridation process or a plasma modification process for the surface of the substrate or a film formed on the substrate using the reactive gas alone. Further, the technique of the present disclosure may also be applied to a plasma annealing process using the reactive gas alone.

The embodiments described above are described by way of an example in which the manufacturing process of the semiconductor device is performed. However, the technique of the present disclosure is not limited thereto. For example, the technique of the present disclosure may be applied to other manufacturing processes. For example, the technique of the present disclosure may be applied to various substrate processings such as a manufacturing process of a liquid crystal device, a manufacturing process of a solar cell, a manufacturing process of a light emitting device, a processing of a glass substrate, a processing of a ceramic substrate and a processing of a conductive substrate.

The first embodiment and the second embodiment described above are described by way of an example in which the substrate processing apparatus is configured to process a single substrate in a single process chamber. However, the technique of the present disclosure is not limited thereto. For example, the technique of the present disclosure may also be applied to a substrate processing apparatus in which a plurality of substrates are arranged in the horizontal direction or the vertical direction.

It is preferable that recipes used in the film-forming process are prepared individually in accordance with process contents and stored in the memory 260c via an electric communication line or the external memory 262. When starting various processes, it is preferable that the CPU 260a selects an appropriate recipe among the recipes stored in the memory 260c in accordance with the process contents. Thus, various films of different composition ratios, qualities and thicknesses can be formed in a reproducible manner and in a universal manner by using a single substrate processing apparatus. In addition, since a burden on an operating personnel of the substrate processing apparatus can be reduced, various processes can be performed quickly while avoiding a misoperation of the substrate processing apparatus. The recipe described above is not limited to creating a new recipe. For example, the recipe may be prepared by changing an existing recipe stored in the substrate processing apparatus in advance. When changing the existing recipe to a new recipe, the new recipe may be installed in the substrate processing apparatus via the electric communication line or the recording medium in which the new recipe is stored. Further, the existing recipe already stored in the substrate processing apparatus may be directly changed to the new recipe by operating the input/output device 261 of the substrate processing apparatus.

According to some embodiments of the present disclosure, it is possible to uniformly form the film on the surface of the substrate by controlling the plasma distribution.

What is claimed is:

1. A substrate processing apparatus comprising:
a process vessel accommodating therein a process chamber where a substrate is processed;
a gas supplier through which a gas is supplied into the process chamber; and
a first plasma generator configured to generate a plasma of the gas in the process chamber and comprising:
an insulator provided so as to protrude into the process chamber;
a coil of a planar shape arranged in the insulator; and
an adjuster capable of adjusting a gap distance between the coil and the insulator.

2. The substrate processing apparatus of claim 1, wherein a distribution of the plasma generated by the first plasma generator at a central portion of the substrate is capable of being adjusted by adjusting the gap distance by the adjuster.

3. The substrate processing apparatus of claim 2, wherein the gap distance is capable of being adjusted by moving the coil vertically inside the insulator by the adjuster.

4. The substrate processing apparatus of claim 1, wherein an amount of the plasma generated by the first plasma generator at a central portion of the substrate is capable of being increased by shortening the gap distance by the adjuster.

5. The substrate processing apparatus of claim 4, wherein the amount of the plasma generated by the first plasma generator at the central portion of the substrate is capable of being increased by shortening the gap distance by moving the coil downward by the adjuster.

6. The substrate processing apparatus of claim 1, wherein an amount of the plasma generated by the first plasma generator at a central portion of the substrate is capable of being decreased by lengthening the gap distance by the adjuster.

7. The substrate processing apparatus of claim 6, wherein the amount of the plasma generated by the first plasma generator at the central portion of the substrate is capable of being decreased by lengthening the gap distance by moving the coil upward by the adjuster.

8. The substrate processing apparatus of claim 1, wherein the gap distance is equal to a distance between the coil and an inner wall at a bottom portion of the insulator along a vertical direction.

9. The substrate processing apparatus of claim 1, wherein the adjuster is provided with a mover configured to move the coil vertically.

10. The substrate processing apparatus of claim 9, wherein the mover comprises a micrometer, and the coil is capable of being moved vertically by rotating the micrometer.

11. The substrate processing apparatus of claim 1, wherein the insulator is of a hemispherical shape provided so as to protrude into the process chamber.

12. The substrate processing apparatus of claim 1, wherein the first plasma generator is shielded by an electromagnetic wave shield of a cylindrical shape or of a rectangular parallelepiped shape constituted by a conductive metal plate.

13. The substrate processing apparatus of claim 1, further comprising:
a second plasma generator configured to generate the plasma of the gas in the process chamber and comprising a second coil arranged outside the process vessel and wound around an outer periphery of the process vessel.

14. A plasma generating apparatus configured to generate a plasma of a gas in a process chamber where a substrate is processed, the plasma generating apparatus comprising:
an insulator of a hemispherical shape provided so as to protrude into the process chamber;
a coil of a planar shape arranged in the insulator; and
an adjuster capable of adjusting a gap distance between the coil and the insulator.

15. The plasma generating apparatus of claim 14, wherein a distribution of the plasma generated at a central portion of the substrate is capable of being adjusted by adjusting the gap distance by the adjuster.

16. The plasma generating apparatus of claim 14, wherein the gap distance is capable of being adjusted by moving the coil vertically inside the insulator by the adjuster.

17. The plasma generating apparatus of claim 14, wherein an amount of the plasma generated at a central portion of the substrate is capable of being increased by shortening the gap distance by the adjuster.

18. A substrate processing method comprising:
(a) loading a substrate into a process chamber of a substrate processing apparatus comprising:
a process vessel accommodating therein the process chamber where the substrate is processed;
a gas supplier through which a gas is supplied into the process chamber; and
a plasma generator configured to generate a plasma of the gas in the process chamber and comprising:
an insulator provided so as to protrude into the process chamber;
a coil of a planar shape arranged in the insulator; and
an adjuster capable of adjusting a gap distance between the coil and the insulator; and
(b) generating the plasma of the gas in the process chamber.

19. A method of manufacturing a semiconductor device, comprising the substrate processing method of claim 18.

20. A non-transitory computer-readable recording medium storing a program that causes a substrate processing apparatus, by a computer, to perform a process comprising the substrate processing method of claim 18.
